(19) United States
(12) Patent Application Publication
(10) Pub. No.: US 2016/0234938 A1
(43) Pub. Date: Aug. 11, 2016

(54) CIRCUIT BOARD ASSEMBLY

(71) Applicant: NOVALIA LTD, Cambridge (GB)

(72) Inventor: Kate STONE, Cambridge (GB)

(21) Appl. No.: 15/022,805

(22) PCT Filed: Sep. 18, 2014
(86) PCT No.: PCT/GB2014/052832

§ 371 Date: Mar. 17, 2016

(30) Foreign Application Priority Data
Sep. 18, 2013 (GB) 1316539.4

(51) Int. Cl. H05K 1/11; H05K 3/32; H05K 1/03; H05K 3/12; H05K 1/18; H05K 1/02

(52) U.S. Cl. CPC H05K 1/111; H05K 1/189; H05K 1/028; H05K 1/0326; H05K 1/0346; H05K 1/032; H05K 1/038; H05K 1/0386; H05K 3/125; H05K 3/1275; H05K 3/321; H05K 2201/0145; H05K 2201/0158; H05K 2201/0329; H05K 2201/10636; H05K 2201/10674; H05K 2201/10727

(57) ABSTRACT

A circuit board assembly is described. The circuit board assembly comprises a circuit board comprising a substrate supporting a plurality of contact lands and a device, such as a bare die or printed circuit board, comprising a plurality of contact pads which is mounted on the circuit board such that the contact pads are aligned with the contact lands. The circuit board assembly comprises an interconnect layer which has a sheet resistance, Rₛ, of at least 0.5 MΩ/sq, which is disposed between the device and the circuit board and which is arranged to provide electrical connections between the contact lands and corresponding contact pads.

### FIELD OF THE INVENTION

The present invention relates to a circuit board assembly.

### BACKGROUND

Electronic components are increasingly being incorporated into printed articles, such as books, posters and greeting cards, to allow printed articles to become more interactive. Examples of interactive printed articles are described in GB 2 464 537 A, WO 2004 077286 A, WO 2007 035115 A and DE 1993 4312672 A.

Interconnections between conventional circuit boards, discrete devices and/or packaged devices can be made using solder re-flow pastes in conjunction with solder resist layers. An example of such an arrangement is described in US 2005/0046023 A1. However, solder re-flow processing is not suited to integrating electronic components into printed articles.

Another method of interconnecting conventional circuit boards, discrete devices and/or packaged devices is to use anisotropic conductive films/layers comprising conductive particles embedded in a non-conductive medium. Examples of such arrangements are described in U.S. Pat. No. 5,629,838 A, WO 2008/065997 A1, EP 1 702 968 A1 and EP 0 260 141 A2.

Other methods interconnecting conventional circuit boards, discrete devices and/or packaged devices have been described. For example, DE 29 02 002 A1 describes monolithically integrating stacks of silicon wafers using layers of conductive adhesive. WO 99/41784 A1 describes interconnecting conventional circuit boards, discrete devices and/or packaged devices using layers of half-conductive materials. Half-conductive liquid/paste/foil layers are described which comprise a mixture of conductive filler particles embedded in a high resistance base material.

Conventionally, discrete devices (such as capacitors) and packaged devices (such as microcontrollers) are mounted to a printed wiring board and the printed wiring board is mounted to or inserted into the printed article, such as a poster or greeting card. However, devices can be directly connected to conductive tracks using conductive glue or tape. Examples of such arrangements are described in GB 2 490 384 A and GB 2 494 223 A.

### Summary

According to a first aspect of the present invention there is provided a circuit board assembly comprising a circuit board which comprises a substrate supporting a plurality of contact lands and a device which comprises a plurality of contact pads and which is mounted on the circuit board such that the contact pads are aligned with the contact lands. The circuit board assembly comprises an interconnect layer which has a sheet resistance, R_{S}, of at least 0.5 MΩ/sq and which is disposed between the device and the circuit board, and which is arranged to provide electrical connections between the contact lands and corresponding contact pads.

Thus, a single interconnect layer can be used to connect pairs of contact pads and lands in parallel thereby making the assembly easier to fabricate.

The interconnect layer may have a sheet resistance, Rₛ, of at least 1 MΩ/sq, at least 2 MΩ/sq or at least 3 MΩ/sq. The interconnect layer may have a sheet resistance, R_{S}, of no more than 1 GΩ/sq, no more than 100 MΩ/sq, no more than 10 MΩ/sq or no more than 10 MΩ/sq.

The separation between adjacent contact pads or contact lands may be greater than or equal to the width of each contact pad or contact land. Thus, the resistance between adjacent contact pads (or lands) is the same as, or more than, the sheet resistance, R_{S}.

The interconnect layer may comprise a homogeneously conductive material. This can simplify production because the distribution of conductive particles within the interconnect layer material/precursor does not need to be controlled during storage and/or application of the interconnect layer.

The ratio of the sheet resistance, R_{S}, to the contact resistance, R_{C}, between a contact pad and the corresponding contact land may be at least 2500:1, at least 10 000:1 or at least 30 000:1. A high resistance ratio provides robustness against signal cross-talk between adjacent pairs of contact pads and contact lands. Thus, a high resistance ratio enables connection of sensitive analogue components via the interconnect layer. The interconnect layer may have a thickness, t, of at least 100 nm, at least 200 nm or at least 500 nm. The interconnect layer may have a thickness, t, of no more than 100 μm, no more than 50 μm or no more than 20 μm.

The interconnect layer may have a thickness, t, which is between 0.1 .tᵣ and 10 .tᵣ, where:

tᵣ=sqrt(R_{C}.A/R_{S})

where R_{C} is contact resistance and A is area of the contact land and/or contact pad.

The interconnect material may comprises a conductive polymer.

The circuit board assembly comprises more than one interconnect layer in the form of separate co-planar pads.

The device may comprise a discrete component. The device may comprise a semiconductor die. The device may be packaged, in other words, the device may be a package. The device may comprise a flat package. The device may comprise a flat no-lead package. The package may be a quad flat package. The device may comprise a microcontroller. The device may comprise a printed circuit board.

The device may be semiconductor die and the substrate may be a package for a semiconductor die.

The substrate may be flexible, for example, capable of being bent by more than 10°. The substrate may comprise a layer of a fibre-based material, such as paper, card or cardboard. The layer may consist mainly of the fibre-based material. Fibre-based material may comprise recycled material.

The substrate may comprise a layer of a plastics material. For example, the substrate may comprise polyethylene terephthalate (PET), polypropylene (PP) or polyethylene naphthalate (PEN).

The substrate may comprise a laminate of at least two layers. For example, the substrate may comprise a layer of fibre-based material covered with a layer of plastic or sandwiched between two layers of plastic.

The lands may comprise conductive ink, such as silver or carbon. The lands may comprise foil. The lands may have a sheet resistance of no more than 1 kΩ/sq, no more than 100 Ω/sq, no more than 10 Ω/sq or no more than 1 Ω/sq. The lands may comprise ends of conductive tracks.

The substrate may support at least one capacitive touch switch and/or array of touch electrodes.

The circuit board assembly may comprise a printed article or part of a printed article supporting printed indicia, such as text and/or images.

The circuit board assembly may comprise a printed article or a part (such as a cover) of printed article. The printed article may be a greeting card, poster, book, product packaging, point-of-sale display, map or pamphlet.

According to a second aspect of the present invention there is provided a method of manufacturing a circuit board assembly. The method comprises applying an interconnect layer which has a sheet resistance, R_{S}, of at least 0.5 MΩ/sq to a device comprising a plurality of contact pads and/or to a circuit board comprising a substrate supporting a plurality of contact lands. The method comprises mounting the device on the circuit board such that the contact pads are aligned with the contact lands and such that the interconnect layer provide electrical connections between the contact lands and corresponding contact pads.

Applying the interconnect layer may comprise printing interconnect material.

According to a third aspect of the present invention there is provided use of an interconnect layer having a sheet resistance, R_{S}, of at least 0.5 MΩ/sq to provide electrical connections between contact lands on a circuit board and corresponding contact pads on a device.

According to a fourth aspect of the present invention there is provided an assembly comprising a support which comprises a substrate supporting a plurality of contact lands and a device which comprises a plurality of contact pads and which is mounted on the support such that the contact pads are aligned with the contact lands. The assembly comprises an interconnect layer which has a sheet resistance, R_{S}, of at least 0.5 MΩ/sq and which is disposed between the device and the support, and which is arranged to provide electrical connections between the contact lands and corresponding contact pads.

The support may be a circuit board.

### BRIEF DESCRIPTION OF THE DRAWINGS

Certain embodiments of the present invention will now be described, by way of example, with reference to the accompanying drawings, in which:

FIG. 1 is a perspective view of an article including a substrate, a device mounted on the circuit board using a interconnect layer;

FIG. 2 is a plan view of a circuit board;

FIG. 3a is a bottom view a device;

FIG. 3b is a side view of a device;

FIGS. 4a, 4b and 4c show first, second and third patterns for the interconnect layer; and

FIG. 5 schematically shows an arrangement of adjacent contact lands and a contact pad.

### DETAILED DESCRIPTION OF CERTAIN EMBODIMENTS

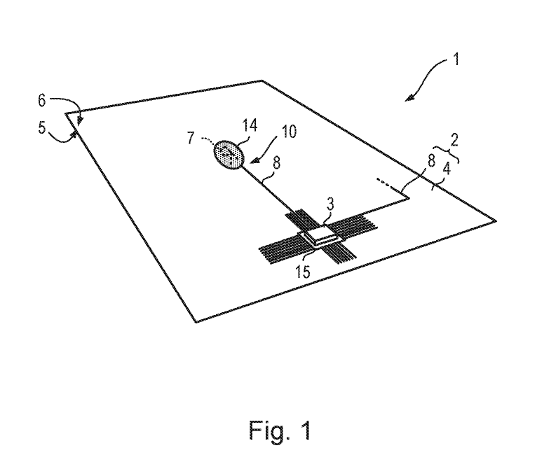

Referring to FIG. 1, a printed article 1 is shown which includes a circuit board 2 and a device 3 mounted to the circuit board 2.

In FIG. 1, only one device 3 is shown for sake of clarity. However, typically several devices are mounted to the circuit board 2 to provide an electronic system which can receive user input, for example, via one or more capacitive touch switches and/or via a wireless network interface and provide output, for example, in the form of light and/or sound signals, and/or via a user device (such as a smart phone) using the wireless network interface.

The circuit board 2 comprises a substrate 4, for example formed of cardboard, having first and second faces 5, 6. The first face 5 of the substrate 4 supports printed indicia 7. The second face 6 of the substrate 4 supports electrically-conductive tracks 8.

The tracks 8 comprise conductive silver ink and are formed by printing using a printing process, such a lithographic printing. However, the tracks 8 may comprise conductive carbon ink which may be formed by printing, or metal foil which may be formed by stamping or patterning and etching a foil film.

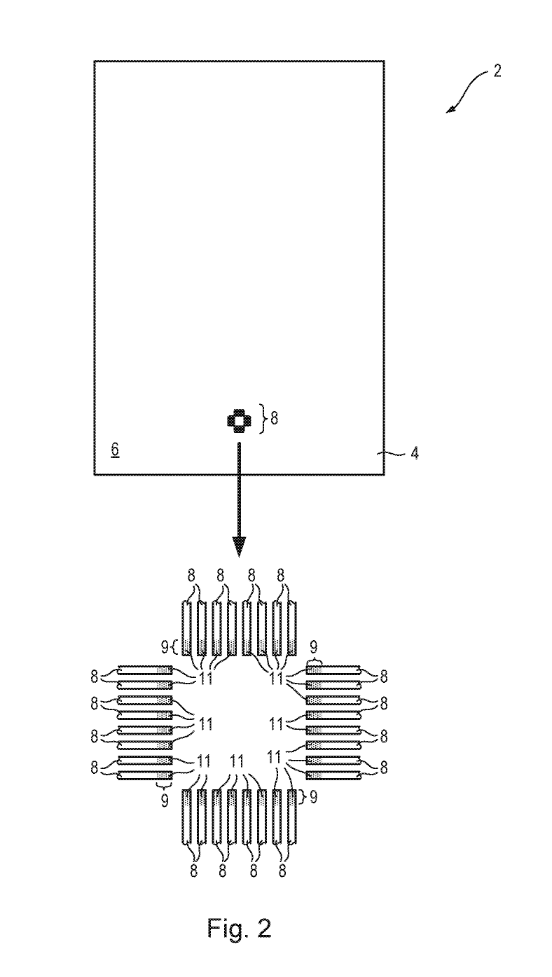

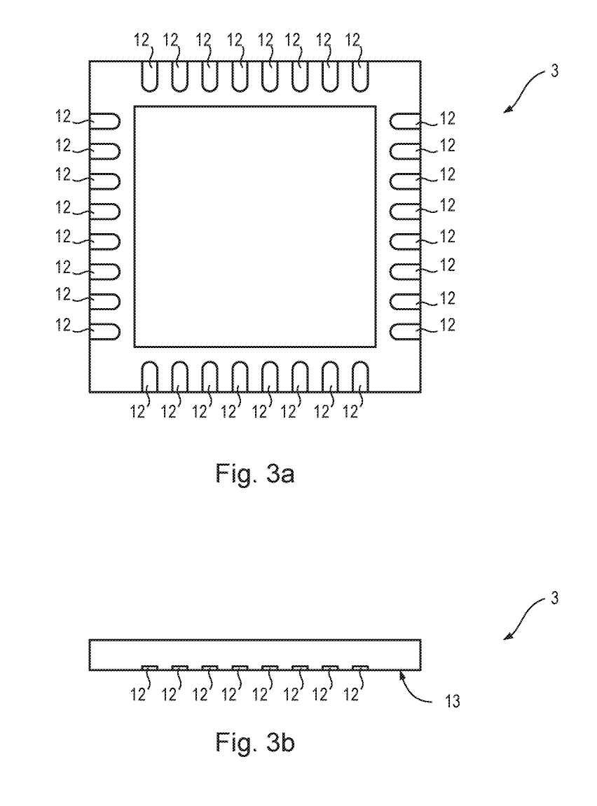

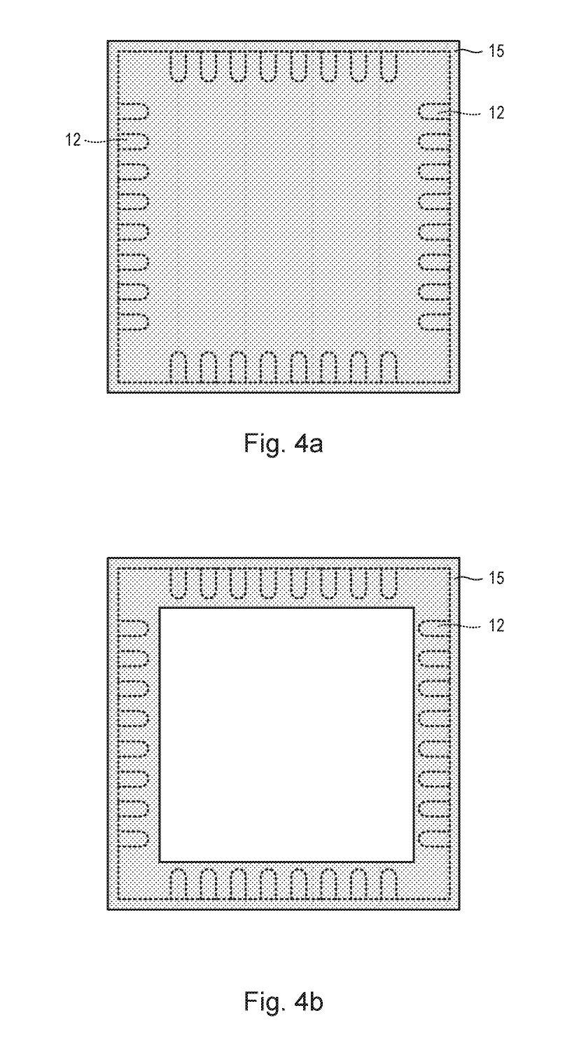

Referring also to FIGS. 2, 3a and 3b, each track 8 includes first and second ends 9, 10. At least some of first ends 9 of the tracks 8 provide (or are provided with) contact lands 11 (shown shaded in FIG. 2) for connecting to corresponding contact pads 12 on an underside surface 13 of the device 3. At least one of the second ends 10 of the tracks 8 has an enlarged region 14 (for example having an area of 1 cm² to 100 cm²) which provides a capacitive touch switch.

The circuit board 2 need not be a conventional printed circuit board (PCB). The circuit board 2 may have (and typically has) the appearance of a traditional printed article, such as poster, map, point-of-sale display, book or magazine.

Referring also to FIG. 3, the device 3 is a microcontroller in the form of a flat no-lead package. However, the device 3 can be an unpackaged device, e.g. a bare die (such as an LED), a discrete component (such as a resistor) or a PCB which supports one or more devices. The device(s) may include a sensor (such as a microphone), an actuator (such as a piezo speaker), coin cell holder or wireless network interface module (such as Bluetooth (RTM)).

Referring still to FIG. 1, the device 3 is mounted to the circuit board 2 using a thin interconnect layer 15 (which may also be referred to as a “pad” or “strip”) which comprises a conductive, but not highly-conductive material, such as lightly-doped conducting polymer, having a sheet resistance, R_{S}, of about 3 MΩ/sq. The interconnect layer 15 is in direct contact the circuit board lands 9 and device pads 12. The interconnect layer 15 preferably functions as an adhesive.

As will be explained later, the thickness of the interconnect layer 15 is chosen to minimise sufficiently leakage between adjacent pads 12, but provide sufficient current between a land 11 and a corresponding pad 12.

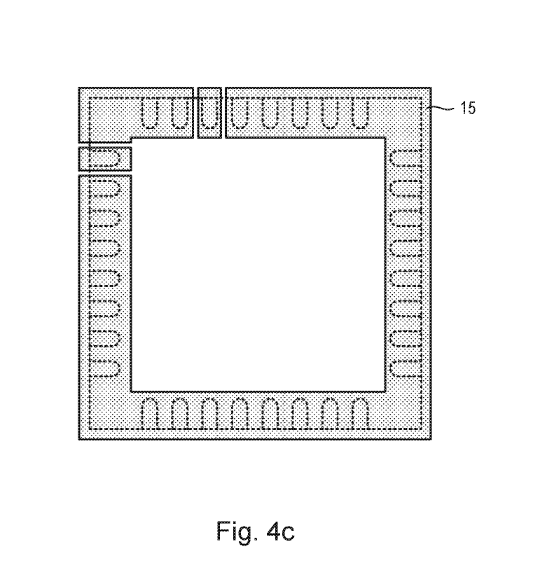

Referring to FIGS. 4a, 4b and 4c different interconnect layer patterns are shown. FIGS. 4a, 4b and 4c shows the outlines of the device 3 and pads 12 in chain to illustrate position of the interconnect layer 15 relative to the device 3.

As shown in FIG. 4a, the interconnect layer 15 may take the form of a solid block of material and be approximately co-extensive with the device 3. As shown in FIG. 4b, the interconnect layer 15 may take the form of annulus. As shown in FIG. 4b, more than one interconnect layer 15 can be used, for example, to isolate pads 12 which are held at high voltages.

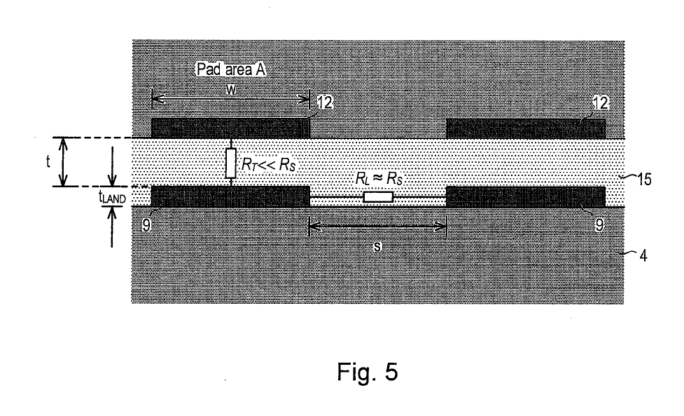

Referring to FIGS. 5 and 6, a non-limiting explanation of the underlying principles of operation will now be given.

The interconnect layer 15 comprises a material which is conductive, but which is generally less conductive than most metals, which tend to have a bulk resistivity, ρ, of about 10⁻⁸ Ωm. For example, the interconnect layer 15 may comprise a material having a bulk resistivity, ρ, which has an order of magnitude in the range of 0.01 to 100 Ωm.

The interconnect layer material is preferably homogeneously conductive, i.e. preferably does not comprise particles of relatively high conductivity embedded in a matrix of relatively low conductivity.

The thickness, t, of the interconnect layer 15 is chosen so that it has a poor sheet resistance. For example, the interconnect layer 15 may have a sheet resistance, R_{S}, which has an order of magnitude of 0.1 MΩ/sq, 1 MΩ/sq or 10 MΩ/sq.

The invention is based on the insight that the resistance, R, between two points in a conductive film is the about the same as the sheet resistance, R_{S}, provided that the points are not too close to the edge or the points effectively map out a square in the material, i.e. the points are found at corners of a block or strip of material that is wide as it is long.

Thus, by making the thickness, t, of the interconnect layer 15 sufficiently small so that the aspect ratio of the block of material between terminals that are to be connected is small, the resistance (herein referred to as the “through resistance” R_{T}) is relatively small, i.e. several orders of magnitude lower than the sheet resistance, R_{S}. However, for adjacent terminals which are not intended to be connected, the resistance is relatively large, i.e. approximately equal to the sheet resistance, R_{S}.

The distance between adjacent pads 9 (or lands 12) can be equal to, or more than, the width of each pad 9 (or land 12). Thus, the resistance between adjacent pads 9 (or lands 12) is the same, as or more than, the sheet resistance, R_{S}.

The material and thickness can be chosen as follows:

First, a sheet resistance, R_{S}, is chosen.

The sheet resistance, R_{S}, is chosen by considering a minimum resistance required between two terminals. For example, a standby current may be used which lies in a range between about 1 μA and about 10 μA. If these currents are driven by a voltage of about 3 V, then resistance between power pins should be 3 MΩ or less. Thus, a sheet resistance, R_{S}, of 3 MΩ/sq is chosen.

Secondly, a through resistance, R_{T}, is chosen.

For example, a microcontroller can typically supply around 25 to 30 mA. For 3 V operation, this gives a through resistance, R_{T}, of 100 Ω.

In this example, the ratio of the sheet resistance, R_{S}, to the through resistance, R_{T}, is 30 000:1. For 3 V operation of a controller using standby currents in the range of 1 μA to 10 μA and supply currents in the range 25 to 30 mA, the minimum ratio of the sheet resistance, R_{S}, to the through resistance, R_{T}, is 2500:1. Larger ratios than 30 000:1 can be used provided the value of the through resistance, R_{T}, can be kept within the desired range.

An estimate of the thickness, t, of the interconnect layer 15 as a function of the through resistance, R_{T}, can be estimated using equation 1 below, namely:

t=sqrt(R_{T}.A/R_{S}) (1)

where A is the area of a pad 12.

Thus, the thickness, t, depends on the area of the pad 12. In particular, if the pad 12 is smaller, then the interconnect layer 15 should be thinner.

For example, if a bare die has a pad length, l, and a pad width, w, of 100 μm, then the pad area, A, is 0.01 mm². If sheet resistance is R_{S}=3 MΩ/sq and the through resistance is R_{T}=100 Ω, then the interconnect layer thickness, t, should be no more than 0.58 μm.

In another example, if the a printed circuit board has a pad length, l, and pad width, w, of 3 mm, then the pad area, A, is 9 mm. If sheet resistance is R_{S}=3 MΩ/sq and the through resistance is R_{T}=100 Ω, then the interconnect layer thickness, t, should be no more than 17 μm.

Having found the thickness, t, of the interconnect layer 15, then the resistivity, ρ, of the material can be found using equation 2 below, namely:

ρ=R_{S}.t (1)

where R_{S} is sheet resistance of the interconnect layer 15 and t is thickness of the layer.

A suitable material can then be found which has the desired resistivity. For instance, a conductive polymer can be found which has the approximate desired resistivity and can be doped to obtain a more precise value of resistivity.

For example, in the case of the bare die, the desired resistivity, ρ, is 1.7 Ωm and in the case of the PCB, the desired resistivity, ρ, is 51 Ωm. For example, PEDOT:PSS doped with DMSO and isopropanol has the desired resistivity.

The interconnect layer 15 can be printed using a printing process, such as ink jet printing or lithographic printing.

Test samples can be fabricated and measured using two- or four-probe resistance measurements to find suitable thicknesses and materials for the interconnect layer 15.

When sensitive analogue devices such as resistive or capacitive touch switches are connected via the interconnect layer 15, the ratio of the sheet resistance, R_{S}, to the through resistance, R_{T}, may be at least 2500:1 and is preferably as large as possible. Digital electronic components can tolerate lower resistance ratios because digital electronics recognise high/low inputs within a range of voltages. By contrast, absolute voltage values are used for analogue components. For example, in a case in which several resistive or capacitive touch switches are connected via the interconnect layer 15, the resistance ratio should preferably be made as large as is practical. When the resistance ratio is sufficiently large, the possibility of erroneous touch switch actuation caused by signal crosstalk between adjacent contact lands or contact pads is reduced. Using a high resistance ratio can also allow the triggering threshold for actuation of user input touch switch(es) to be kept low so that a user may easily actuate the touch switch(es).

It will be appreciated that many modifications may be made to the embodiments hereinbefore described.

A interconnect layer material can be chosen which wets the pad and/or lands, but not the substrate or rest of the device.

The arrangement can be used to package parts, for example, a semiconductor die in a package.

1. A circuit board assembly comprising:
a circuit board comprising a substrate supporting a plurality of contact lands;
a device comprising a plurality of contact pads which is mounted on the circuit board such that the contact pads are aligned with the contact lands; and
an interconnect layer which has a sheet resistance, R_{S}, of at least 0.5 MΩ/sq and which is disposed between the device and the circuit board and which is arranged to provide electrical connections between the contact lands and corresponding contact pads.

2. A circuit board assembly according to claim 1, wherein the separation between adjacent contact pads or contact lands is greater than or equal to the width of each contact pad or contact land.

3. A circuit board assembly according to claim 1, wherein the interconnect layer comprises a homogeneously conductive material.

4. A circuit board assembly according to claim 1, wherein the ratio of the sheet resistance, R_{S}, to the contact resistance, R_{C}, between a contact pad and the corresponding contact land is at least 2500:1, at least 10 000:1 or at least 30 000:1.

5. A circuit board assembly according to claim 1, wherein the interconnect layer has a sheet resistance, R_{S}, of at least 1 MΩ/sq, at least 2 MΩ/sq or at least 3 MΩ/sq.

5. (canceled)

6. A circuit board assembly according to claim 1, wherein the interconnect layer has a thickness, t, of at least 100 nm.

7. A circuit board assembly according to claim 1, wherein the interconnect layer has a thickness, t, of no more than 100 μm.

8. A circuit board assembly according to claim 1, wherein the thickness, t, is between 0.1.tᵣ and 10.tᵣ, where:
tᵣ=sqrt(R_{C}.A/R_{S})
where R_{C} is contact resistance and A is area of the contact land and/or contact pad.

9. A circuit board assembly according to claim 1, wherein the interconnect material comprises a conductive polymer.

10. A circuit board assembly according to claim 1, wherein the interconnect layer is patterned into at least two separate co-planar pads.

11. A circuit board assembly according to claim 1, wherein the device comprises a flat package, such as flat no-lead package.

12. A circuit board assembly according to claim 11, wherein the device comprises microcontroller.

13. A circuit board assembly according to claim 1, wherein the device comprises a printed circuit board.

14. A circuit board assembly according to claim 1, wherein the circuit board is a package for semiconductor die.

15. A circuit board assembly according to claim 14, wherein the device is a semiconductor die.

16. A circuit board assembly according to claim 1, wherein the substrate is flexible.

17. A circuit board assembly according to claim 1, wherein the substrate comprises a layer of a fibre-based material.

18. A circuit board assembly according to claim 17, wherein the fibre-based material is paper, card or cardboard.

19. A circuit board assembly according to claim 17, wherein the layer consists mainly of the fibre-based material.

20. A circuit board assembly according to claim 1, wherein the substrate comprises a layer of a plastics material.

21. A circuit board assembly according to claim 1, wherein the substrate comprises a laminate of at least two layers.

22. A circuit board assembly according to claim 1, wherein the substrate supports at least one capacitive touch switch and/or array of touch electrodes.

23. A circuit board assembly according to claim 1, wherein the circuit board assembly comprises a printed article or part of a printed article supporting printed indicia.

24. A method of manufacturing a circuit board assembly, the method comprising:
applying an interconnect layer to a device comprising a plurality of contact pads and/or to a circuit board comprising a substrate supporting a plurality of contact lands; and
mounting the device onto a circuit board such that the contact pads are aligned with the contact lands and such that the interconnect layer provide electrical connections between the contact lands and corresponding contact pads.

25. A method according to claim 24, wherein the applying the interconnect layer comprises printing material.

26. The use of an interconnect layer having a sheet resistance, R_{S}, of at least 0.5 MΩ/sq to provide electrical connections between contact lands on a circuit board and corresponding contact pads on a device.

27. A circuit board assembly according to claim 1, wherein the interconnect layer has a sheet resistance, R_{S}, of no more than 1 GΩ/sq.
